(19) United States
(12) Patent Application Publication
(10) Pub. No.: US 2013/0130502 A1
(43) Pub. Date: May 23, 2013

(54) MICROMECHANICAL MEMBRANES AND RELATED STRUCTURES AND METHODS

(71) Applicant: Sand 9, Inc., Cambridge, MA (US)

(72) Inventors: Andrew Sparks, Cambridge, MA (US); Jan H. Kuypers, Cambridge, MA (US); Klaus Juergen Schoepf, Chandler, AZ (US); Reimund Rebel, Maricopa, AZ (US)

(73) Assignee: Sand 9, Inc., Cambridge, MA (US)

(21) Appl. No.: 13/673,321

(22) Filed: Nov. 9, 2012

Related U.S. Application Data
(63) Continuation-in-part of application No. 13/112,587, filed on May 20, 2011.
(60) Provisional application No. 61/347,169, filed on May 21, 2010.
(60) Provisional application No. 61/558,680, filed on Nov. 11, 2011.

(51) Int. Cl. H01L 21/302

(52) U.S. Cl. CPC H01L 21/302
USPC 438/702

(57) ABSTRACT

Micromechanical membranes suitable for formation of mechanical resonating structures are described, as well as methods for making such membranes. The membranes may be formed by forming cavities in a substrate, and in some instances may be oxidized to provide desired mechanical properties. Mechanical resonating structures may be formed from the membrane and oxide structures.

### RELATED APPLICATIONS

This application claims the benefit under 35 U.S.C. §120 as a continuation-in-part of U.S. patent application Ser. No. 13/112,587 filed May 20, 2011 under Attorney Docket No. G0766.70020US01 and entitled “Micromechanical Membranes and Related Structures and Methods,” which claims the benefit under 35 U.S.C. §119(e) of U.S. Provisional Patent Application Ser. No. 61/347,169, filed on May 21, 2010 under Attorney Docket No. G0766.70020US00 and entitled “Micromechanical Membranes and Related Structures and Methods.”

This application also claims the benefit under 35 U.S.C. §119(e) of U.S. Provisional Patent Application Ser. No. 61/558,680 filed Nov. 11, 2011 under Attorney Docket No. G0766.70020US02 and entitled “Micromechanical Membranes and Related Structures and Methods.”

All of the foregoing applications are hereby incorporated herein by reference in their entireties.

### BACKGROUND

1. Field

The technology described herein relates to micromechanical membranes and related structures and methods.

2. Related Art

Some microelectromechanical systems (MEMS) devices, including some MEMS oscillators, include a micromechanical resonating component or structure. The micromechanical resonating structure vibrates in response to electrical or mechanical excitation, with the vibration being used to generate an electrical signal. The resonating structure is typically on the order of several hundred microns or smaller.

Micromechanical resonating structures are typically formed of single crystal silicon because of perceived benefits of the material. Vibrating structures fabricated out of silicon exhibit low damping. In addition, silicon is readily available. Furthermore, numerous fabrication processes for working with silicon wafers have been established, and these processes can be used to precisely shape silicon to obtain a well controlled geometry for purposes of forming a silicon resonating structure.

### SUMMARY

According to an aspect of the present application, a method is provided comprising forming a silicon membrane above a cavity in a silicon substrate, the silicon membrane having a first thickness, and forming a layer of material having a second thickness on top of the silicon membrane to create a membrane having a third thickness, the third thickness representing a sum of the first and second thicknesses.

According to an aspect of the present application, a method is provided, comprising forming a layer of material on a silicon substrate, forming a plurality of trenches in the layer of material, and annealing the substrate after forming the plurality of trenches in the layer of material on the silicon substrate.

According to an aspect of the present application, a method is provided comprising forming a plurality of trenches in a silicon substrate, depositing a conformal layer of material in the plurality of trenches, and annealing the substrate after depositing the conformal layer of material in the plurality of trenches.

### BRIEF DESCRIPTION OF THE DRAWINGS

Various aspects and embodiments of the technology will be described with reference to the following figures. It should be appreciated that the figures are not necessarily drawn to scale. Items appearing in multiple figures are indicated by the same reference number in all the figures in which they appear.

FIGS. 1A and 1B illustrate a cross-sectional view and a top view, respectively, of a membrane formed on a substrate and suitable for forming a micromechanical resonating structure, according to one non-limiting embodiment.

FIGS. 2A and 2B illustrate a cross-sectional view and a top view, respectively, of an oxidized membrane formed on a substrate and suitable for forming a micromechanical resonating structure, according to another non-limiting embodiment.

FIGS. 3A and 3B illustrate a perspective view and a cross-sectional view, respectively, of a resonating structure formed from a membrane, according to another non-limiting embodiment.

FIG. 4 illustrates a cross-sectional view of a structure including multiple membranes formed on a substrate and each suitable for forming a micromechanical resonating structure, according to another non-limiting embodiment.

FIGS. 5A and 5B illustrate a cross-sectional view and a top view, respectively, of trench patterns which may be used to form the structure of FIG. 4, according to one non-limiting embodiment.

FIGS. 6A-6C illustrate alternative apparatus including membranes of different thicknesses together with differing oxide configurations, according to alternative non-limiting embodiments.

FIGS. 7A-7H illustrate top views of non-limiting examples of one-dimensional trench patterns which may be used to form membrane structures according to various non-limiting embodiments.

FIGS. 8A-8F illustrate top views of non-limiting examples of two-dimensional trench patterns which may be used to form membrane structures according to various non-limiting embodiments.

FIGS. 9A-9B illustrate cross-section views of a non-limiting alternative approach for forming membranes of a desired thickness.

FIGS. 10A-10F illustrate a non-limiting process of forming membranes involving selective epitaxial growth.

FIGS. 11A-11D illustrate a non-limiting alternative process for forming membranes according to the techniques described herein.

FIGS. 12A-12D illustrate an alternative technique for membrane formation, according to a non-limiting embodiment.

### DETAILED DESCRIPTION

While the previously described perceived benefits of silicon account for its use in micromechanical resonating structures, silicon may also exhibit temperature dependent properties (such as a temperature dependent stiffness tensor) which are undesirable in some situations. Thus, temperature changes may induce temperature drift in devices utilizing silicon micromechanical resonating structures, such as temperature drift in oscillator signals generated by oscillators having silicon resonating structures. Temperature compensation of silicon resonating structures may be achieved by placement of compensating structures on the top and bottom of the silicon resonating structure. A non-limiting example of such a temperature compensation structure includes a layer of silicon oxide on both the top and bottom of the silicon resonating structure, as described in U.S. patent application Ser. No. 12/639,161, filed Dec. 16, 2009 under Attorney Docket No. G0766.70006US01, published as U.S. Patent Publication No. 2010/0182102 and entitled “Mechanical Resonating Structures Including A Temperature Compensation Structure,” which is hereby incorporated herein by reference in its entirety. The silicon oxide may react differently than the silicon to changes in temperature, for example exhibiting different stiffening behavior, which thus may compensate for temperature-induced variations in behavior (e.g., operating frequency or resonance frequency) of the silicon resonating structure.

Applicants have appreciated that silicon membranes suitable for forming micromechanical resonating structures may be formed using empty-space-in-silicon (ESS) principles, and furthermore that oxidation of such silicon membranes may then be performed to form temperature compensated structures. Thus, according to one aspect of the present application, silicon membranes suitable for formation of micromechanical resonating structures are formed from a silicon substrate. The dimensions of the membranes (e.g., thickness and area) may be selected to facilitate subsequent formation of a mechanical resonating structure having desired vibratory characteristics. The silicon membranes may be formed using ESS principles, as will be further described below, and in some embodiments may be oxidized to form temperature-compensated structures.

Applicants have further appreciated that ESS principles may be used to form multiple silicon membranes on the same silicon substrate, which may be used to form distinct micromechanical resonating structures, for instance to be used in different MEMS devices. Moreover, Applicants have appreciated that it may be beneficial in some instances to form, on the same substrate, silicon membranes of different thicknesses and/or with different oxide configurations, for example to provide devices incorporating such structures with different mechanical properties (e.g., vibratory properties).

Thus, according to another aspect of the present application, two or more silicon membranes are formed on the same silicon substrate and differ in one or more respects which may impact the vibratory characteristics of the membranes and thus the vibratory characteristics of resonating structures formed from the membranes. According to one such aspect, two or more of the silicon membranes may differ in their thicknesses, which therefore may result in the membranes exhibiting different vibratory characteristics. According to another such aspect, differing oxide configurations may be formed with respect to two or more of the silicon membranes. The oxide configurations may differ in terms of the presence or absence of oxide, the location of oxide, and/or the thickness of oxide.

According to another aspect of the present application, multiple silicon membranes are formed on a silicon substrate using different trench patterns in conjunction with ESS principles. The trench patterns may differ in terms of the area of the openings of the trenches, the depths of the trenches, the aspect ratios of the trenches and/or the pitches of the trench patterns. Annealing of the silicon substrate after formation of the trenches may then result in silicon membranes of differing dimensions (e.g., different thicknesses), as a result of the differing trench patterns.

The aspects described above, as well as additional aspects, are described further below. These aspects may be used individually, all together, or in any combination of two or more, as the technology is not limited in this respect.

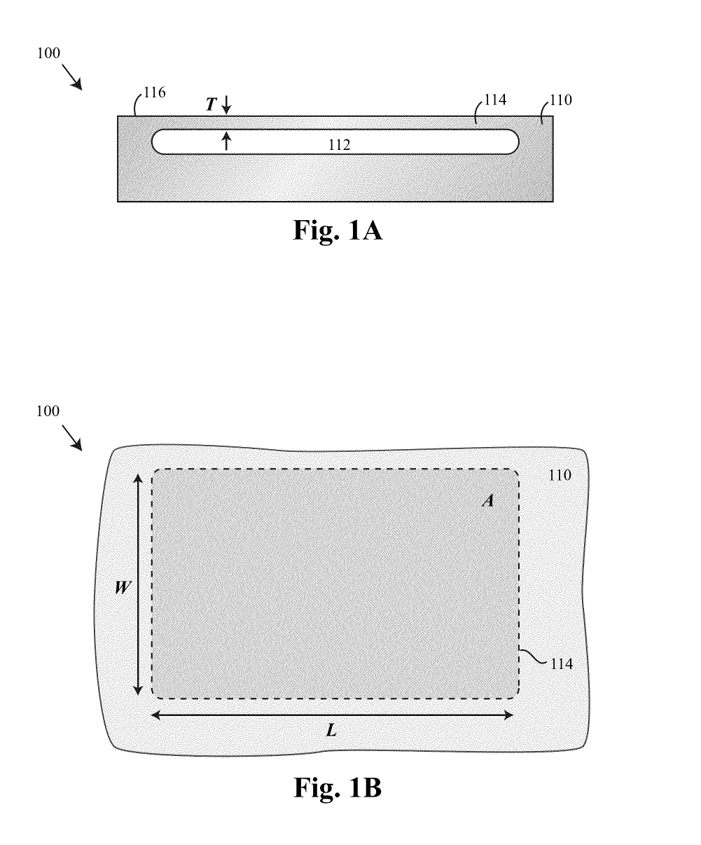

FIGS. 1A and 1B illustrate a cross-section and a top view, respectively, of an apparatus including a silicon membrane formed on a silicon substrate and suitable for formation of a mechanical resonating structure, according to one non-limiting embodiment of a first aspect of the present application. The apparatus 100 includes a substrate 110 in which a cavity 112 is formed. The substrate 110 has a top surface 116. The substrate may be a silicon substrate, and in some embodiments may be a single crystal silicon substrate, though not all embodiments are limited in this respect, as other materials (e.g., glass) may alternatively be used. For example, the substrate may be a silicon-on-insulator (SOI) substrate, where either the device layer or the handle is used for membrane formation (e.g., membrane 114, described below). The substrate may be of any other suitable material and may comprise a single crystal layer composed of the same or other material or may comprise layers of different materials that could be single crystalline, polycrystalline or amorphous. The cavity 112 may be formed using ESS principles (i.e., formation of a trench in the substrate followed by an anneal), and may be an air cavity, a vacuum, or any other type of cavity. A membrane 114 is formed above, and defined by, the cavity 112, and is formed of the same material as that of which the substrate 110 is formed (e.g., silicon, and in some non-limiting embodiments, single crystal silicon, although other materials may alternatively be used). The membrane 114 is generally of the same crystallinity as the substrate 110 (e.g., single crystalline, polycrystalline, or amorphous) but this may be controlled to some degree by the details of the anneal process. The membrane 114 is outlined by the dashed line in FIG. 1B.

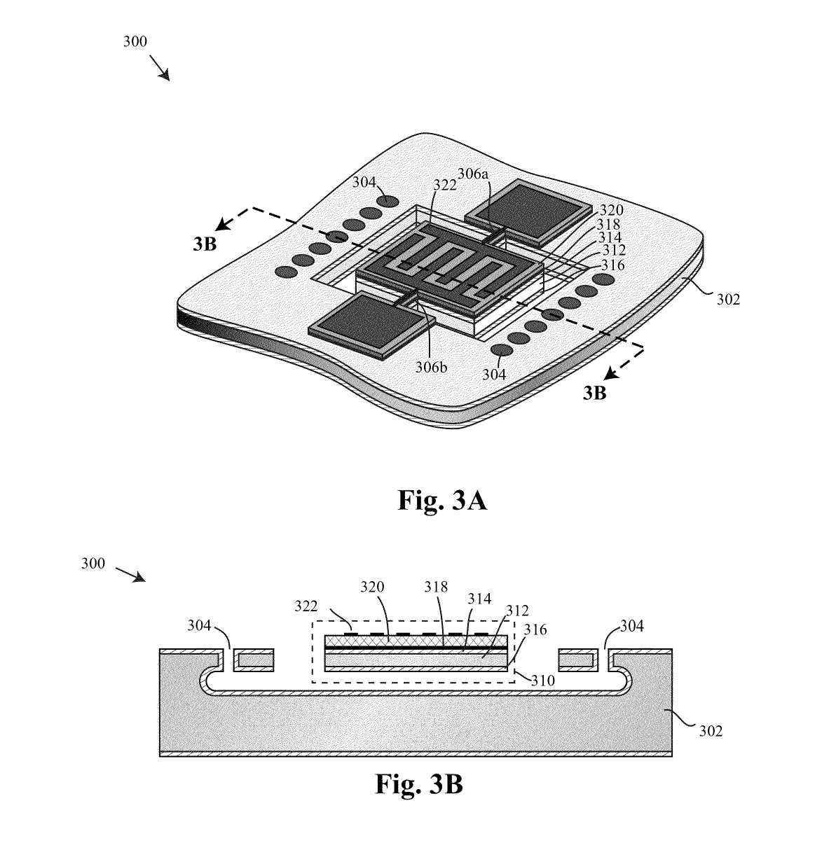

As mentioned, according to the present aspect, the membrane 114 may be suitable for formation of a mechanical resonating structure (e.g., by defining such a structure from the membrane, as will be described further below in connection with FIGS. 3A and 3B), by proper shaping and dimensioning of the membrane. As shown in FIGS. 1A and 1B, the membrane 114 has a thickness T, and an area A defined by a length L and a width W (although it should be appreciated that the membrane is not limited to the illustrated rectangular shape). The dimensions T, L, and W may be selected such that membrane 114 is suitable for subsequent formation of a resonating structure having desired vibratory characteristics.

According to one non-limiting embodiment, to provide suitable vibratory characteristics, the membrane thickness T may be between approximately 1 and 20 microns. According to another embodiment, T may be between approximately 1 and 10 microns (e.g., 2 microns, 5 microns, etc.). According to one embodiment, T may be less than approximately three wavelengths of a resonance frequency of interest of a mechanical resonating structure to be formed from the membrane. According to some embodiments, the thickness T is less than approximately two wavelengths of a resonance frequency of interest of a resonating structure to be formed from the membrane. In still other embodiments, the thickness T may be less than approximately one wavelength of a resonance frequency of interest (e.g., less than approximately one wavelength of a resonant Lamb wave supported by a mechanical resonating structure to be formed from the membrane). Thus, it should be appreciated that the thickness of the membrane may determine or depend on the types of waves to be supported by a resonating structure to be formed from the membrane. For example, a given thickness may limit the ability of the resonating structure to support Lamb waves, or certain modes of Lamb waves. Thus, the thickness may be chosen dependent on the types and/or modes of waves desired to be supported by a mechanical resonating structure to be formed from the membrane. According to any of those embodiments described above, the thickness T may be substantially uniform (as shown in FIG. 1A), although not all embodiments are limited in this respect.

According to one embodiment, suitable vibratory characteristics of the membrane 114 may be provided by suitably selecting not only the thickness of the membrane, but also at least one other dimension (e.g., length or width) of the membrane. For instance, suitable selection of the ratio of the thickness (T) to the maximum dimension of L and W (i.e., the larger of L and W) may provide suitable vibratory characteristics of the membrane such that the membrane is suitable for formation of a mechanical resonating structure (e.g., a micromechanical resonating structure to be used in a MEMS oscillator). According to one non-limiting embodiment, the ratio of T to the larger of L and W is between 1:20 and 1:500 (e.g., 1:100, 1:200, 1:300, 1:400, etc.). According to an alternative embodiment, the ratio of T to the larger of L and W is between 1:20 and 1:100 (e.g., 1:20, 1:50, etc.). It should be appreciated that other ratios are also possible, and that those listed are provided for purposes of illustration and not limitation. It should also be appreciated that the rectangular shape of the membrane 114 illustrated in FIG. 1B is not limiting, and that other shapes are also possible, and therefore that, in some embodiments, the membrane may not be characterized by a substantially constant length and width. Even so, suitable dimensioning of the thickness T to the area A, regardless of the shape of the membrane, may provide suitable vibratory characteristics.

In any of those embodiments described above, or any other embodiments described herein in which the membrane has a length (L) and width (W), L and W may have any suitable values. For example, one or both of L and W may be less than approximately 1000 microns, less than approximately 100 microns (e.g., 75 microns, 60 microns, 50 microns, 40 microns, or any other value within this range), between approximately 50 microns and 200 microns, between approximately 70 microns and 120 microns, between approximately 30 microns and 400 microns, or have any other suitable values. Also, L and W need not be the same, and may differ by any suitable amounts, as the various aspects described herein as relating to membranes having dimensions L and W are not limited in this respect. According to some embodiments, L and W may be selected such that the area A is between approximately 110% and 300% (e.g., approximately 120%, approximately 150%, approximately 230%, approximately 250%, etc.) of the area of a mechanical resonating structure to be formed from the membrane, or in other embodiments between approximately 110% and 200% of the area of a mechanical resonating structure to be formed from the membrane, as described below.

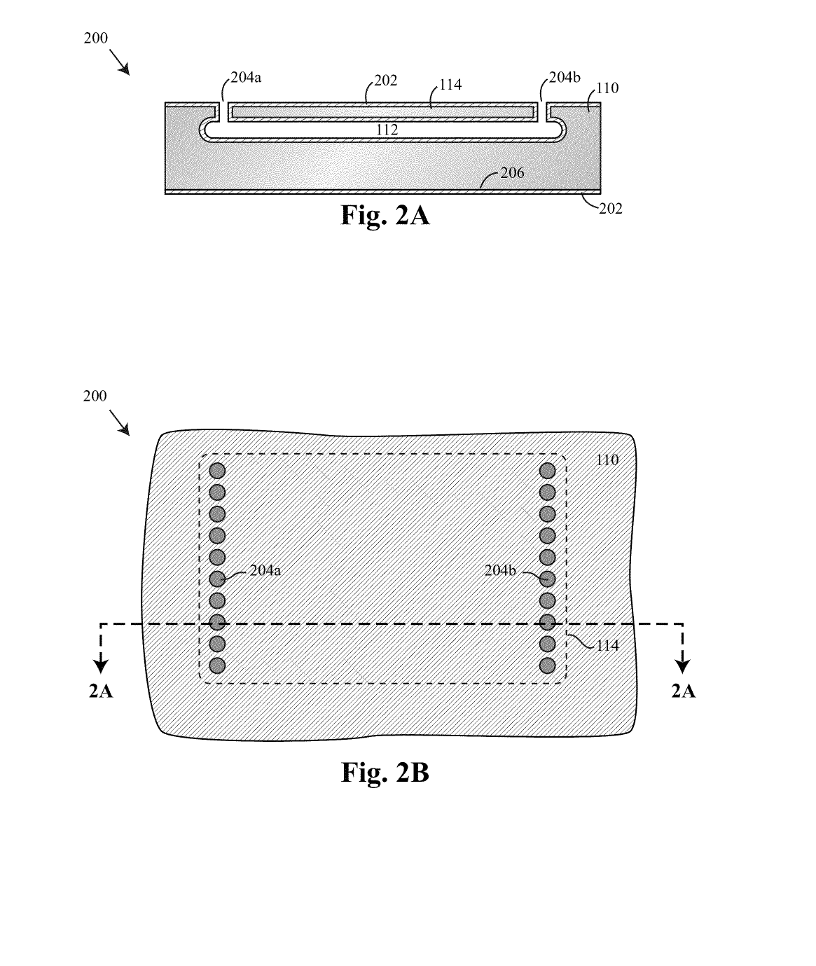

According to one aspect of the present application, a membrane (e.g., a single crystal silicon membrane) formed on a substrate (e.g., a single crystal silicon substrate) and suitable for formation of a mechanical resonating structure (e.g., a micromechanical resonating structure) is oxidized to provide a temperature compensated structure of the type(s) previously described with respect to U.S. patent application Ser. No. 12/639,161 (i.e., including silicon sandwiched between two layers of silicon oxide). A non-limiting example is illustrated in FIGS. 2A (cross section) and 2B (top view).

The illustrated apparatus 200 is similar to the apparatus 100 of FIG. 1A, with the addition of an oxide layer. As shown, the oxide layer 202 is formed on various surfaces of the structure, including on the membrane 114 (both the top and bottom surfaces of the membrane, in this non-limiting example), within the cavity 112 (i.e., on the walls of the cavity 112), and on the backside 206 of the substrate 110. The apparatus 200 includes access holes 204a and 204b, which are formed prior to formation of the oxide to provide access to the cavity 112 and therefore the backside (or bottom) of the membrane 114. By first forming the access holes 204a and 204b, the subsequent oxidation of the structure may produce the illustrated oxide configuration within the cavity 112 and on the bottom surface of the membrane 114.

The access holes may be of any suitable number and positioning, as well as each having any suitable size and shape, to facilitate formation of a desired oxide configuration (e.g., oxidizing the cavity 112 and/or the bottom of the membrane 114). FIG. 2B illustrates the device 200 in a top down view (with the oxide represented by the diagonal patterning), showing a non-limiting example of the size, shape, number, and arrangement of the access holes 204a and 204b. Variations are possible, and the various embodiments of the present application are not limited to the illustrated details.

To form the oxide illustrated in FIGS. 2A and 2B, after formation of the access holes, the silicon wafer or substrate may undergo thermal oxidation. Thermal oxidation may involve heating the wafer at a temperature typically between 850° C. and 1200° C., for example at 1100° C., in an atmosphere containing oxygen. Depending on the oxidizing conditions (e.g., temperature, wet or dry environment, etc.), pressure, and number and dimensions of the access holes, as well as the distance from the access holes to the center of the cavity, the thickness of the oxide on the bottom surface (or backside) of the membrane may be controlled to be substantially the same as or identical to the thickness of the oxide on the top surface of the membrane. According to some embodiments, the thickness of the oxide formed on the bottom surface of the membrane may be thinner than that formed on the top surface, for example, by between 2%-5%, between 2%-10%, between 10%-15%, or between 15%-20%, as non-limiting examples. The oxide thickness, however, may be accurately controlled and highly repeatable by use of a suitable access hole design.

As mentioned, the formation of the SiO₂—Si—SiO₂ multi-layer structure of apparatus 200 may provide temperature compensated functionality. Suitable selection of the ratio of the thickness of the silicon membrane to the total thickness of the silicon oxide layer(s) (e.g., the combined thickness of oxide layers on the top and bottom surfaces of the membrane) may provide for temperature compensation of a desired acoustic mode of vibration for a resonating structure formed from the membrane. For example, the ratio of the total thickness of the silicon oxide on the top and bottom surfaces of the membrane (when oxide is present on both the top and bottom surfaces of the membrane) to the silicon of the membrane may be between 1:0.1 and 1:10, between 1:0.5 and 1:3, between 1:0.75 and 1:1.25, or between 1:1 and 1:2, among other possible ratios. Thus, suitable values of the thickness of the oxide layer(s) may be determined from these ratios by reference to the suitable values of the thickness T of the membrane, described above.

Utilizing ESS principles with a subsequent oxidation step to form the oxidized structure illustrated in FIGS. 2A and 2B may be beneficial compared to alternative manners of forming a layer of silicon between two layers of silicon oxide, some of which alternatives may include use of a silicon-on-insulator (SOI) substrate. For example, using the techniques described herein, oxidation of the top and bottom surfaces of the membrane 114 may occur simultaneously (or substantially simultaneously), which may minimize or eliminate bowing of the membrane. In addition, formation of the silicon oxide within the cavity 112 and on the backside 206 of the substrate 110 may minimize or eliminate bowing of the substrate 110, thus facilitating further processing of the apparatus 200. In addition, the thickness of the membrane 114 may be controlled with high accuracy (e.g., to within ±0.02 microns) using the techniques described herein, a degree of control which may not be possible using SOI techniques with an SOI wafer (which may only have accuracy to ±0.5 microns). With the processes described herein, oxidation layers several micrometers thick, e.g., 0.1 μm to 3 μm, may be formed easily and with a very high degree of precision.

As mentioned, membranes of the type described herein may be utilized to form a mechanical resonating structure that may serve as part or all of a MEMS device, such as a MEMS oscillator. A non-limiting example is illustrated in FIGS. 3A and 3B, with FIG. 3A providing a perspective view and FIG. 3B providing a more detailed cross-sectional view.

The illustrated device 300 includes a micromechanical resonating structure 310 (reference number shown in FIG. 3B) that includes a silicon layer 312, a silicon oxide layer 314 on the top surface of the silicon layer 312, and a silicon oxide layer 316 on the bottom surface of the silicon layer 312. Thus, the layering structure of the micromechanical resonating structure 310 is substantially the same as that of the membrane 114 and silicon oxide 202 illustrated in FIG. 2A. According to one embodiment, the micromechanical resonating structure 310 may be formed by first forming the apparatus 200 of FIG. 2A and subsequently defining the micromechanical resonating structure from the membrane 114 (e.g., by lithography, etching or any other suitable technique). The device 300, as shown (after definition of the mechanical resonating structure from the membrane), does not include a membrane, since the act of defining the micromechanical resonating structure from the membrane effectively alters the nature of the structure such that it is no longer a membrane.

Formation of the micromechanical resonating structure 310 from a membrane, like that of FIG. 2A, may result in the micromechanical resonating structure being connected to a substrate by two or more anchors. As shown in FIG. 3A, the micromechanical resonating structure 310 is connected to the substrate 302 by two anchors, 306a and 306b, which may be flexible in some embodiments. The number of anchors is not limiting, as any suitable number may be used. It should further be understood that the geometry of the anchors may be matched to a specific length to reduce the amount of acoustic energy transferred from the micromechanical resonating structure to the substrate. Suitable anchor structures that reduce stress and inhibit energy loss have been described in U.S. patent application Ser. No. 12/732,575, filed Mar. 26, 2010 under Attorney Docket No. G0766.70005US01, published as U.S. Patent Publication No. 2010/0314969 and entitled “Mechanical Resonating Structures and Methods”, which is hereby incorporated herein by reference in its entirety.

As illustrated in the cross-section of the device 300 shown in FIG. 3B, the micromechanical resonating structure 310 may include additional components beyond the layers 312, 314, and 316. For example, a bottom conducting layer 318 may be included, as well as an active layer 320 (e.g., a piezoelectric layer, for example made of aluminum nitride, or any other suitable piezoelectric material), and one or more top electrodes 322. Not all the illustrated components are required and other components may be included in some embodiments, as the illustration provides a non-limiting example of a resonating structure. A non-limiting example of the positioning of the access holes 304, which may be substantially the same as the previously-described access holes 204a and 204b, with respect to the micromechanical resonating structure 310 is illustrated.

As mentioned, various types and forms of mechanical resonating structures may be formed from suitable membranes (e.g., single crystal silicon membranes) according to the various aspects described herein, and FIGS. 3A and 3B provide only a non-limiting example. For example, the mechanical resonating structure may comprise or be formed of any suitable material(s) and may have any composition. According to some embodiments, the mechanical resonating structure may comprise a piezoelectric material (e.g., active layer 320). According to some embodiments, the mechanical resonating structure comprises quartz, LiNbO₃, LiTaO₃, aluminum nitride (AlN), or any other suitable piezoelectric material (e.g., zinc oxide (ZnO), cadmium sulfide (CdS), lead titanate (PbTiO₃), lead zirconate titanate (PZT), potassium niobate (KNbO₃), Li₂B₄O₇, langasite (La₃Ga₅SiO₁₄), gallium arsenside (GaAs), barium sodium niobate, bismuth germanium oxide, indium arsenide, indium antimonide), either in substantially pure form or in combination with one or more other materials. Moreover, in some embodiments in which the mechanical resonating structure comprises a piezoelectric material, the piezoelectric material may be single crystal material, although in other embodiments including a piezoelectric material the piezoelectric material may be polycrystalline.

The mechanical resonating structure may have any shape, as the shape illustrated in FIGS. 3A and 3B is a non-limiting example. For example, aspects of the technology may apply to mechanical resonating structures that are substantially rectangular, substantially ring-shaped, substantially disc-shaped, or that have any other suitable shape, as any such shapes may be defined from a suitable membrane of the types described herein. As additional, non-limiting examples, the configuration of the mechanical resonating structure can include, for example, any antenna type geometry, as well as beams, cantilevers, free-free bridges, free-clamped bridges, clamped-clamped bridges, discs, rings, prisms, cylinders, tubes, spheres, shells, springs, polygons, diaphragms and tori. Moreover, the mechanical resonating structure may have one or more beveled edges. According to some embodiments, the mechanical resonating structure may be substantially planar. Moreover, geometrical and structural alterations can be made to improve quality (e.g., Q-factor, noise) of a signal generated by the mechanical resonating structure.

The mechanical resonating structures described herein may have any suitable dimensions, and in some embodiments may be micromechanical resonating structures. The mechanical resonating structure may have a thickness corresponding to the thickness of a membrane (plus any oxidation layers on the membrane) from which the mechanical resonating structure is defined, and thus may have any of the thicknesses previously described with respect to the thickness T.

According to some embodiments, the mechanical resonating structures described herein have a large dimension (e.g., the largest of length, width, diameter, circumference, etc. of the mechanical resonating structure) of less than approximately 1000 microns, less than approximately 100 microns, less than approximately 50 microns, or any other suitable value. It should be appreciated that other sizes are also possible. According to some embodiments, the devices described herein form part or all of a microelectromechanical system (MEMS).

The mechanical resonating structures may have any desired resonance frequencies and frequencies of operation, and may be configured to provide output signals of any desired frequencies. For example, the resonance frequencies and/or frequencies of operation of the mechanical resonating structures, and the frequencies of the output signals provided by the mechanical resonating structures, may be between 1 kHz and 10 GHz. In some embodiments, they may be in the upper MHz range (e.g., greater than 100 MHz), or at least 1 GHz (e.g., between 1 GHz and 10 GHz). In some embodiments, they may be at least 1 MHz (e.g., 13 MHz, 26 MHz) or, in some cases, at least 32 kHz. In some embodiments, they may be in the range of 30 to 35 kHz, 60 to 70 kHz, 10 MHz to 1 GHz, 1 GHz to 3 GHz, 3 GHz to 10 GHz, or any other suitable frequencies. Thus, it should be appreciated that the frequencies are not limiting, and that the membranes described herein may be designed to support such frequencies.

The mechanical resonating structures may be operated in various acoustic modes, including but not limited to Lamb waves, also referred to as plate waves including flexural modes, bulk acoustic waves, surface acoustic waves, extensional modes, translational modes and torsional modes. The selected mode may depend on a desired application of the mechanical resonating structure.

The mechanical resonating structure may be actuated and/or detected in any suitable manner, with the particular type of actuation and/or detection depending on the type of mechanical resonating structure, the desired operating characteristics (e.g., desired mode of operation, frequency of operation, etc.), or any other suitable criteria. For example, suitable actuation and/or detection techniques include, but are not limited to, piezoelectric techniques, electrostatic techniques, magnetic techniques, thermal techniques, piezoresistive techniques, any combination of those techniques listed, or any other suitable techniques. The various aspects of the technology described herein are not limited to the manner of actuation and/or detection.

According to some embodiments, the mechanical resonating structures described herein may be piezoelectric Lamb wave devices, such as piezoelectric Lamb wave resonators. Such Lamb wave devices may operate based on propagating acoustic waves, with the edges of the structure serving as reflectors for the waves. For such devices, the spacing between the edges of the resonating structure may define the resonance cavity, and resonance may be achieved when the cavity is an integer multiple of p, where p=λ/2, with λ, being the acoustic wavelength of the Lamb wave of interest, understanding that the device may support more than one mode of Lamb waves. However, it should be appreciated that aspects of the technology described herein apply to other types of structures as well, and that Lamb wave structures are merely non-limiting examples.

It should be appreciated from the foregoing and from FIGS. 3A and 3B that in some embodiments membranes as described herein may be used to form suspended mechanical resonating structures. For example, mechanical resonating structures formed from such membranes may, in some embodiments, have one or more free sides or ends. However, those embodiments described herein in which mechanical resonating structures are formed from a membrane are not limited to the mechanical resonating structures being suspended.

As mentioned, Applicants have appreciated that in some instances it may be beneficial to form two or more membranes (e.g., single crystal silicon membranes) having different vibratory characteristics on the same substrate, such that the membranes may be incorporated into different devices (e.g., distinct oscillators) with different vibratory characteristics. Thus, according to another aspect, two or more silicon membranes may be formed on a silicon substrate, with the membranes differing in thickness. According to yet another aspect, two or more silicon membranes may be formed on a silicon substrate and differing oxide configurations may be formed with respect to the silicon membranes, such that differing mechanical characteristics may be provided.

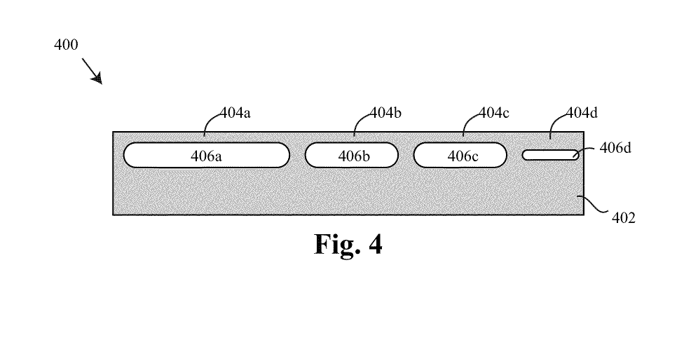

FIG. 4 illustrates a non-limiting example of an apparatus 400 including multiple silicon membranes formed on a silicon substrate 402 (although it should be appreciated that silicon is a non-limiting example of material). As shown, the apparatus includes four silicon membranes, 404a-404d, which are formed above, and defined by, respective cavities 406a-406d. As shown, the membranes do not overlap each other in this non-limiting example, as the cavities do not overlap each other (i.e., none of cavities 406a-406d overlies one of the other cavities in this non-limiting example). The cavities may be formed using ESS principles, by annealing of suitable trench formations. Each of the membranes 404a-404d may have dimensions (e.g., length, width, thickness) suitable to provide desired vibratory characteristics, such that devices having micromechanical resonating structures may be formed from each of the membranes. Thus, the non-limiting examples of dimensions described above with respect to membrane 114 may apply for each of the membranes 404a-404d.

As shown, at least two of the membranes (e.g., membrane 404a and 404d) may have differing thicknesses, and may furthermore have differing areas, although not all embodiments are limited in this respect. The differing thicknesses may result in the membranes exhibiting different vibratory characteristics, which may lead to differing behavior of mechanical resonating structures formed from the different membranes. Thus, the thickness of each membrane may be selected to provide desired vibratory characteristics, and the differences in thickness may therefore depend on the differences in desired vibratory characteristics. According to one embodiment, a thickness of one membrane may differ from a thickness of a second membrane by between approximately 1 micron and 20 microns (e.g., 2 microns, 5 microns, 10 microns, etc.). According to another embodiment, a thickness difference of two membranes may be between approximately 1 micron and 10 microns, and according to a further embodiment the difference may be between approximately 3 and 10 microns.

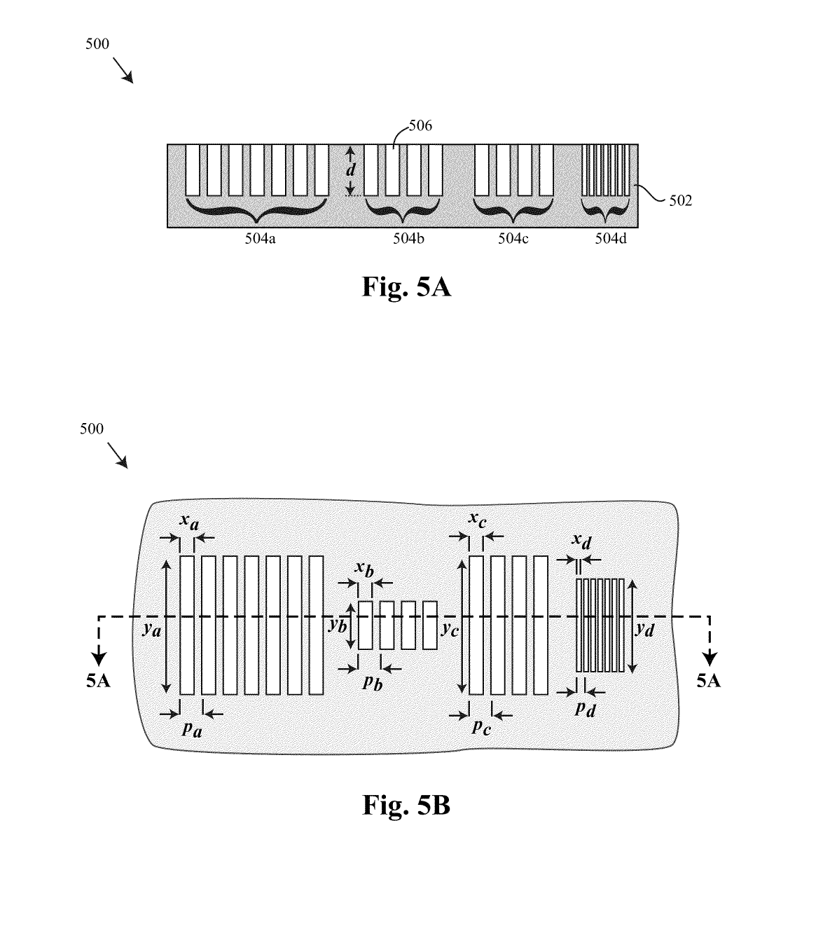

An apparatus including multiple silicon membranes of differing thicknesses, such as apparatus 400 of FIG. 4, may be formed by annealing suitable trench patterns in a substrate (e.g., a silicon substrate). Thus, according to one aspect of the present application, an apparatus includes a substrate with a plurality of trench patterns formed therein, suitable for subsequent annealing to form a corresponding plurality of membranes of different thicknesses. The shape(s) and size(s) (including thickness) of the membranes may be controlled by suitable design of the corresponding trench patterns, including the area of the openings of the trenches, the depth of the trenches, the aspect ratios of the trenches, the shape(s) of the openings of the trenches, and/or the pitch between trenches. Thus, according to the present aspect of the application, the plurality of trench patterns on the substrate may differ in one or more of these trench parameters to produce membranes of different thicknesses. According to one embodiment, the trench patterns may be one dimensional trench patterns comprising a plurality of trenches. A non-limiting example is illustrated in FIGS. 5A (cross section) and 5B (top view).

As shown, the apparatus 500 in this non-limiting example includes a substrate 502 (e.g., a silicon substrate or any other type of substrate described herein) with four distinct trench patterns, 504a-504d, each of which is a one dimensional trench pattern (as will be seen and described further with respect to FIG. 5B) and each of which may be used to form a membrane. Each of the patterns may be characterized by a number of trenches 506, the depth of the trenches of the pattern, the area of the openings of the trenches of the pattern (shown in FIG. 5B), the aspect ratio of the trenches of the pattern (i.e., the ratio of the depth of the trench to the width of the opening of the trench), the shape of the openings of the trenches, and the pitch of the patterns. The patterns may differ in any one or more of these parameters as suitable to create a resulting membrane of a differing thickness. In general, the greater the depth of the trenches, the thicker the membrane; the smaller the aspect ratio of the trenches, the thinner the membrane; the greater the area of the trench openings, the thinner the membrane; and the greater the pitch, the thicker the membrane. However, it should be appreciated that these are general guidelines, and that suitable selection of the combination of the these factors may be used to produce a membrane of a desired thickness.

In the non-limiting example of FIGS. 5A and 5B, pattern 504a includes seven trenches, patterns 504b and 504c each include four trenches, and pattern 504d includes seven trenches. However, other numbers of trenches may be used, and in some embodiments each pattern may have the same number of trenches.

In the non-limiting example of FIGS. 5A and 5B, the trenches of each pattern have the same depth d. However, it should be appreciated that not all embodiments are limited in this respect, as using patterns with trenches of different depths is one way in which membranes of different thicknesses may be formed. In addition, it is not necessary for all the trenches of a pattern (e.g., all the trenches of pattern 504a) to have the same depth as each other. According to one embodiment, trenches within a pattern may have different depths.

As shown in FIG. 5B, the area of the openings of the trenches of the various trench patterns may differ. For example, as shown, the area of the openings of the trenches of pattern 504a (i.e., the area defined by xₐ×yₐ) may differ from the area of the openings of the trenches of pattern 504d (i.e., the area defined by x_{d}×y_{d}). The pitches may also differ (e.g., the pitch pₐ may differ from one or more of p_{b}, p_{c}, and p_{d}). Also, according to some embodiments, the trenches of a trench pattern need not all be separated by the same pitch. For example, some of the trenches may be closer together than others within the pattern (i.e., a pattern need not be characterized by a single pitch). Other variations are also possible.

According to one embodiment, multiple one-dimensional trench patterns are formed in a substrate, with each being suitable to form a membrane. At least some trenches of a first pattern have a first opening area and a first depth. At least some of the trenches of the first pattern are spaced by a first pitch. At least some trenches of a second pattern have a second opening area and a second depth, and at least some of the trenches of the second pattern are spaced by a second pitch. According to one embodiment, at least one of the following conditions is met: (a) the first depth differs from the second depth; (b) the first opening area differs from the second opening area; and (c) the first pitch differs from the second pitch.

Thus, it should be appreciated that FIGS. 5A and 5B provide a non-limiting example of a substrate including four one-dimensional trench patterns from which four membranes may be formed, and that variations are possible. The various parameters of the trenches, including the area of the openings, the depth, and therefore the aspect ratios of the trenches, as well as the pitch of the trenches within each pattern may be selected to provide a desired membrane thickness.

As can be seen from FIG. 5B, each of the patterns 504a-504d is a one dimensional pattern of a plurality of trenches, even though the trenches themselves are obviously not one dimensional. The patterns are one-dimensional in that the trenches of the patterns are arranged in a single dimension (i.e., the x-dimension in this example), as opposed to having multiple trenches in two dimensions (i.e., in both the x and y dimensions, as would be true of an array). Such one dimensional patterns may allow for the use of relatively simple masks for forming the trenches.

The trenches may be formed using various anisotropic dry etching techniques, including, but not limited to, deep reactive ion etching (DRIE), which is often used in combination with a cyclic passivation deposition (the combination being referred to as Bosch process or advanced silicon etch (ASE)). Alternatively, the trenches may also be formed by anisotropic wet etching techniques, including KOH, EDP and TMAH based etch chemistries as well as anodization based etch techniques. Depending on the parameters, i.e., the current density during the anodization process, the silicon might not be completely etched. It should be understood that in some cases the trenches will contain porous silicon residue.

As mentioned, the resulting apparatus (e.g., apparatus 500 of FIG. 5A) may then be annealed to form membranes as shown in FIG. 4. The anneal may be in a hydrogen atmosphere at, for example, 1100° C. and 10 Torr for several minutes. The resulting membranes may be stress free and made of the substrate material (e.g., single crystal silicon).

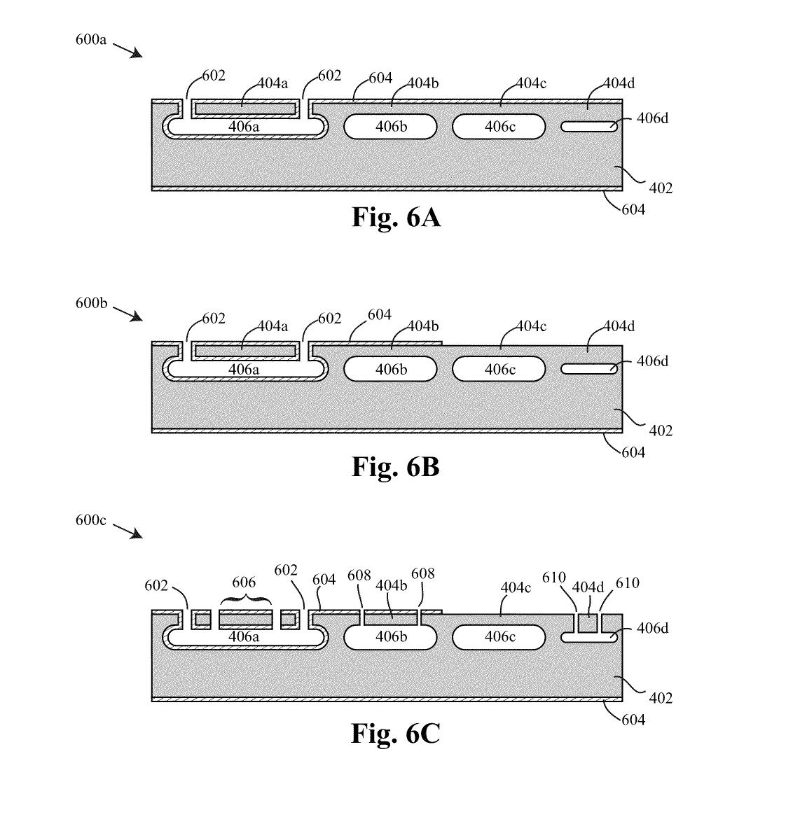

As mentioned, Applicants have also appreciated that it may be beneficial in some instances to form multiple membranes on the same substrate with different oxide configurations, as the oxide configurations may impact the mechanical properties (e.g., the vibratory properties) of the structures and therefore different oxide configurations may result in structures with different vibratory characteristics. Thus, according to one aspect of the present application, multiple membranes with different oxide configurations are formed on the same substrate. The oxide configurations may differ in terms of the presence or absence of oxide, the positioning/location of oxide, and/or the thickness of oxide, all of which may impact the mechanical properties of the structures. In addition, the membranes may differ in thickness. Three non-limiting examples are illustrated in FIGS. 6A-6C.

FIG. 6A illustrates a first non-limiting example of an apparatus including membranes of different thicknesses together with different oxide configurations formed for at least some of the membranes. The apparatus 600a is similar to the apparatus 400 of FIG. 4 and therefore many of the same reference numbers are used to illustrate elements that are the same in both FIGS. 4 and 6A. Thus, as shown, the apparatus 600a includes the substrate 402 on which the four membranes 404a-404d are formed, above respective cavities 406a-406d. As previously explained, at least some of the membranes may have different thicknesses. For example, membrane 404a may have a different thickness than membrane 404d.

In addition, as illustrated, different oxide configurations may be formed with respect to the membranes. In the non-limiting example of FIG. 6A, the oxide configuration formed with respect to membrane 404a differs from that formed with respect to membranes 404b-404d. As shown, oxide 604 is formed on both the top and bottom surfaces of membrane 404a (which may be accomplished by oxidizing the structure after formation of access holes 602), as well as within the cavity 406a. By contrast, oxide 604 is only formed on the top surfaces of membranes 404b-404d, but not on the bottom surfaces of those membranes or within the cavities 406b-406d. Oxide 604 is also formed on the backside of the substrate 402, which, as previously mentioned, may minimize or prevent entirely bowing of the substrate.

The apparatus 600b of FIG. 6B is another non-limiting example of an apparatus including membranes of different thicknesses together with different oxide configurations formed for at least some of the membranes. The apparatus 600b differs from apparatus 600a of FIG. 6A in that the oxide 604 is not formed on the top surfaces of membranes 404c and 404d. One manner of achieving this structure is by forming the apparatus 600a and then suitably removing (e.g., by etching) the oxide 604 overlying membranes 404c and 404d, although other methods of formation are also possible.

The apparatus 600c of FIG. 6C is another non-limiting example of an apparatus including membranes of different thicknesses together with different oxide configurations formed for at least some of the membranes. Here, a mechanical resonating structure 606 has been formed from the membrane 404a, such that the membrane 404a no longer remains. In addition, access holes 608 and 610 are formed to access cavities 406b and 406d, respectively.

Subjecting the apparatus 600c to further oxidation may result in the formation of oxide within cavities 406b and 406d (but not within 406c) and therefore on the back surfaces of membranes 404b and 404d. It should be appreciated that such further oxidation (subsequent to formation of access holes 608 and 610) may result in different oxide thicknesses being formed on different portions of the apparatus. For example, since oxide 604 is already present on portions of the apparatus (e.g., within the cavity 406a and on the membrane 404b), further oxidation of the structure may deposit further oxide on those portions of the apparatus already having oxide. Thus, as an example, subjecting the apparatus 600c to oxidation may result in thicker oxide formed on the backside of the substrate 402, within cavity 406a, on resonating structure 606, and on the top surface of membrane 404b compared to any oxide formed within cavities 406b and 406d and on the top surfaces of membranes 404c and 404d. The oxide thicknesses may differ by between approximately 0.1 microns to 3 microns (e.g., by 0.5 microns, 1 micron, 1.5 microns, 2 microns, 2.5 microns, etc.), as a non-limiting example.

According to one embodiment, the apparatus 600c may be used to form multiple resonating structures. For example, as shown, the apparatus 600c includes resonating structure 606. Resonating structures may also be formed from membranes 404b and 404d, for example, such that three resonating structures with different oxide configurations and/or different thicknesses may be formed on the same substrate. These structures may then be used in distinct devices (e.g., in three different oscillators) exhibiting different operating characteristics.

It should be appreciated from FIGS. 6A and 6C that various membrane structures (including corresponding oxide configurations) may be designed with different mechanical (e.g., vibratory) properties. Therefore, various different mechanical resonating structures may be formed to include such membrane structures. For example, according one embodiment a first membrane may form part of a timing oscillator while a second membrane may form part of a gyroscope. Other configurations are also possible.

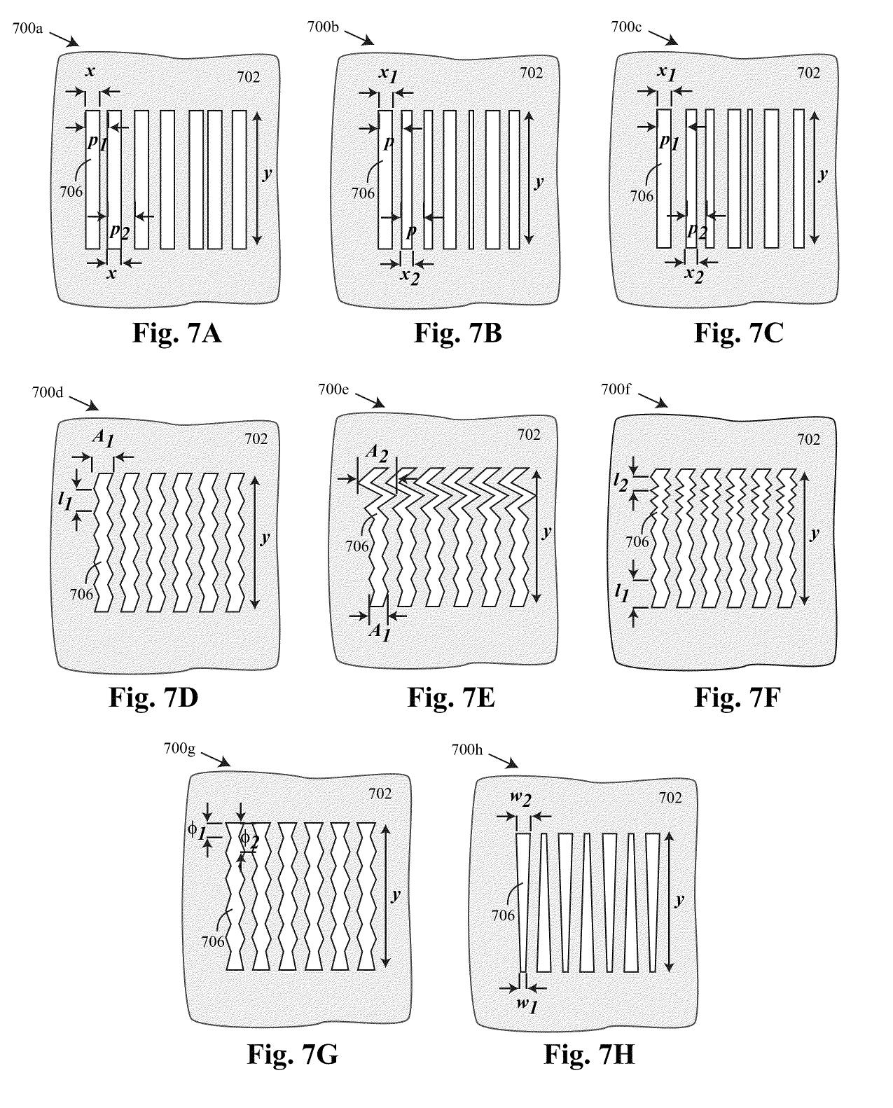

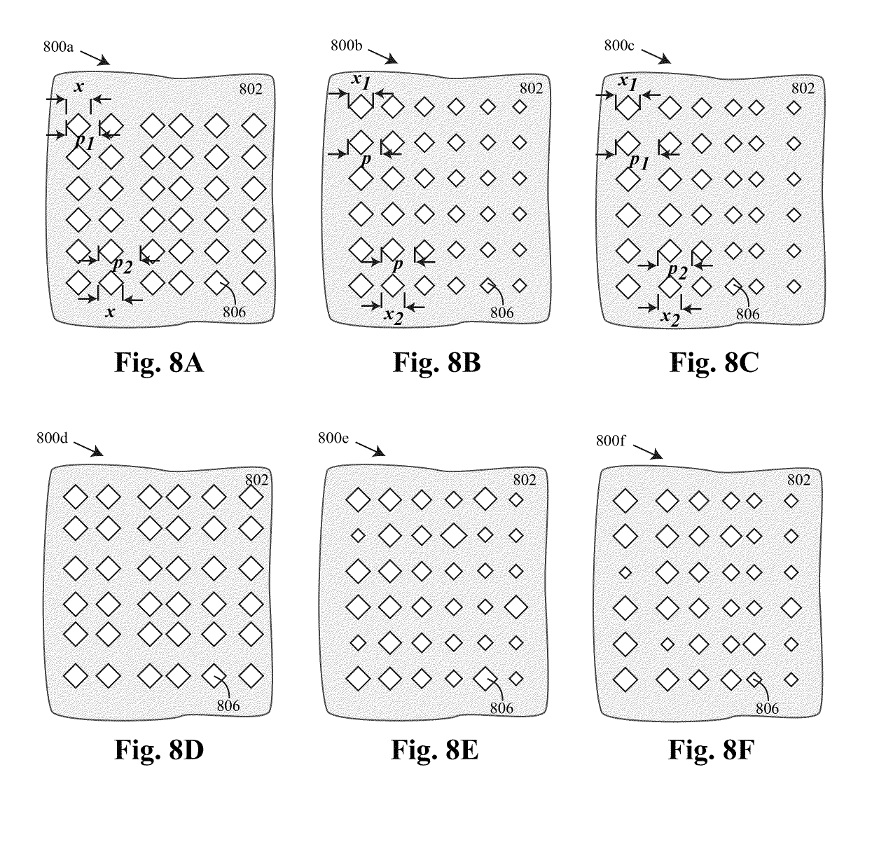

While some non-limiting examples of trench patterns suitable for forming membranes of the types described herein have been shown and described (e.g., see FIGS. 5A and 5B), it should be appreciated that alternatives are possible. FIGS. 7A-7H illustrate top views of non-limiting examples of suitable alternatives to the types of one-dimensional trench patterns illustrated in FIG. 5B which may be used to form membrane structures of the types described herein. As illustrated in FIGS. 7A-7H, and described further below, suitable one-dimensional trench patterns may include trenches that are width-modulated and/or frequency modulated and/or phase-modulated. According to some embodiments, a pattern may include trenches of differing/variable widths and/or trenches that are spaced by a variable pitch. FIGS. 8A-8F illustrate top views of non-limiting examples of two dimensional patterns of trenches which may be used to form membrane structures. The two-dimensional patterns may have trenches exhibiting variable width and/or variable pitch in one or both dimensions of the pattern. Further description is provided below.

FIGS. 7A-7C illustrate various one-dimensional trench patterns (more specifically, the openings of the trenches) in the surface of a substrate 702 (e.g., a silicon substrate) which may be used to form membrane structures of the types described herein by annealing the substrate after forming the trenches 706. In each of FIGS. 7A-7C, the trenches 706 have a length y. The pattern 700a of FIG. 7A features a constant trench width x across the pattern, but with variable pitch p, e.g., p₁≠p₂. The pitch may vary from trench-to-trench according to a repeating pattern, may vary randomly, or may vary in any other suitable manner. The variable pitch may also be referred to as a variable period, i.e., the pattern 700a may be characterized by a variable period.

The pattern 700b of FIG. 7B features a constant pitch p across the pattern, but with variable trench width, e.g., x₁≠x₂. The width of any two or more trenches of the pattern may differ by any suitable amount.

The pattern 700c of FIG. 7C features both variable pitches, e.g., p₁≠p₂ and variable trench widths, e.g., x₁≠x₂. The variation in pitch and/or width throughout the pattern may take any suitable form.

The patterns of FIGS. 7A-7C may be used to compensate for known or anticipated manufacturing variations. For example, it is known that the etch depth using silicon deep reactive ion etching (DRIE) is strongly dependent on the etch loading, relating to the amount of open area being etched in the vicinity of an etched feature. Considering as an example the array of trenches illustrated in FIG. 7A, the leftmost trench will be etched faster than a trench in the center of the pattern if certain etching technologies (e.g., DRIE) are used. Varying the trench width, pitch, or both may be used to compensate for such etching effects, for example to provide more uniform etch depth for the entire pattern of trenches. Alternatively, varying the trench width, pitch, or both may be used to intentionally obtain different etch depths of the trenches despite being etched at the same time. Furthermore, varying the trench width, pitch, or both may be utilized to obtain membranes with thickness gradients or regions with different thicknesses. Such membranes having thickness gradients or regions with different thicknesses may be of interest for making some mechanical structures, for example acoustic resonators operating in a thickness extensional mode and similar to the plano-convex design of quartz bulk acoustic wave resonators.

FIGS. 7D-7H illustrate further non-limiting examples of trench patterns formed in a substrate surface, featuring trench openings that vary along the direction of length y. The pattern 700d of FIG. 7D features a trench opening shape that varies approximately sinusoidally along the y direction with wavelength l₁ and amplitude A₁, the amplitude being the trench width plus the peak-to-peak spatial variation of the opening. The trenches of pattern 700d may be thought of as being width-modulated. It should be understood that width-modulation is not limited to sinusoidal variations and that other suitable functions exist.

The pattern 700e of FIG. 7E features trenches having an amplitude-modulated shape with amplitude varying within a range of A₁ and A₂ in the direction of y.

The pattern 700f of FIG. 7F features trenches with a frequency-modulated shape with wavelength varying within a range of l₁ and l₂ in the direction of y.

The pattern 700g of FIG. 7G illustrates a non-limiting example of phase-modulated trenches. As shown, the phase on the left side of the trench (φ₁) differs from the phase on the right side of the trench (φ₂). It should be appreciated that by adjusting the phase (φ₁) the structure of 700d is translated into the structure 700g. It should also be understood that the phase is not constant, but rather varies across the length of the trench to account for fabrication variations or to accomplish a design objective.

The pattern 700h of FIG. 7H illustrates another non-limiting example featuring trenches having a width-modulated shape, with width varying within a range of w₁ and w₂ in the direction of y.

The patterns in FIGS. 7D-7H may be used to control the evolution of the membrane formation during the anneal process. As such, these pattern features shown in FIGS. 7D-7H may be combined with each other and with the features illustrated in FIGS. 7A-7C. In general, it should be understood that any two or more of the trench pattern features illustrated in FIGS. 7A-7H may be combined.

FIGS. 8A-8C illustrate top views of non-limiting examples of two-dimensional patterns of diamond-shaped trenches 806 in a substrate 802 which may be used to form membrane structures by annealing the substrate after forming the trenches. The choice of the base geometry, in this case diamonds, is arbitrary, and thus it should be appreciated that other geometries are possible. For example, many other polygons are also suitable. The patterns illustrated in FIGS. 8A-8C have trenches 806 of differing sizes (e.g., widths), have variable pitch, or a combination of the two, along either one or two dimensions. Thus, the illustrated patterns represent alternatives to two-dimensional arrays that utilize trenches of the same size and a constant pitch, and may be thought of as “irregular arrays.”

The pattern 800a of FIG. 8A features a constant trench width x across the pattern, but with variable pitch p in the direction of x, e.g., p₁≠p₂. The pattern 800b of FIG. 8B features a constant pitch p across the pattern, but with variable trench width in the direction of x, e.g., x₁≠x₂. The pattern 800c of FIG. 8C features both variable pitches in the direction of x, e.g., p₁≠p₂, and variable trench widths in the direction of x, e.g., x₁≠x₂. The patterns of FIGS. 8A-8C may be used to compensate for known or anticipated manufacturing variations, for example of the types described above with respect to FIGS. 7A-7H.

FIGS. 8D-8F illustrate further non-limiting examples of two-dimensional patterns of diamond-shaped trenches in the surface of a substrate. FIGS. 8D, 8E, and 8F are analogous to FIGS. 8A, 8B, and 8C, respectively, except that variations in pitch and width occur along two axes, i.e., along both dimensions in the plane of the substrate surface. The patterns of FIGS. 8D-8F may be used to compensate for known or anticipated manufacturing variations, for example of the types previously described.

In general, it should be understood that any two or more of the trench pattern features illustrated in FIGS. 8A-8F may be combined.

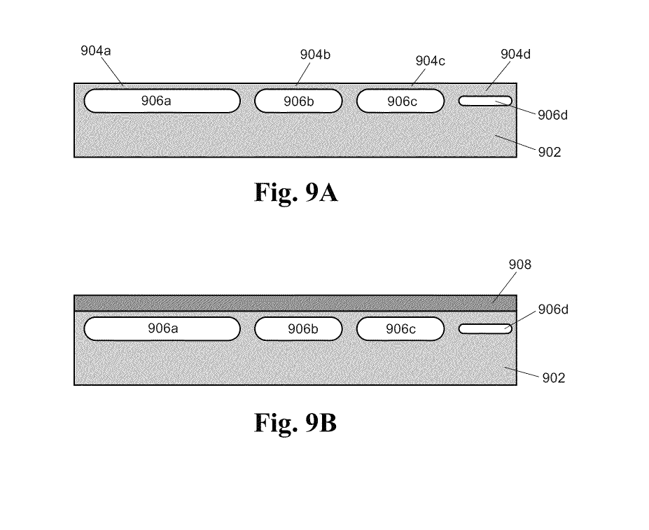

Various techniques for forming membranes have been described thus far. To expedite membrane formation and alleviate the high temperatures and low pressures sometimes needed for reflow according to at least some of the aspects described herein, several techniques may be employed, non-limiting examples of which are now described. In some embodiments, the trench reflow process may be faster (and in some scenarios much faster) with smaller trenches of the same aspect ratio (depth divided by width) as larger trenches which would result in longer reflow times, in at least some embodiments. However, smaller trenches result in thinner membranes. Thus, one approach for creating membranes of a desired thickness is to create membranes thinner than what is ultimately desired, as illustrated in FIG. 9A, and then deposit a film of material on top of the membranes to increase their thicknesses by the same amount (see FIG. 9B).

Referring to FIG. 9A, a silicon substrate 902 may have membranes 904a-904d formed above respective cavities 906a-906d using any of the techniques described herein. The thickness of one or more of the membranes 904a-904d may be less than that desired in some embodiments. For example, the membranes 904a-904d may be formed using relatively small trenches for the purpose of facilitating rapid reflow and membrane formation, which may result in membrane thicknesses less than that desired for certain applications.

As shown in FIG. 9B, thicker membranes may be created by forming (e.g., by deposition) an additional layer 908 on top of the membranes 904a-904d, resulting in effective membranes (the combinations of 908 and 904a, 908 and 904b, 908 and 904c, and 908 and 904d) of greater thickness than the membranes 904a-904d alone. In some embodiments, the additional layer 908 may be deposited, and thus may be a deposited film. For example, the deposited film may be epitaxial Si, either doped or undoped, grown on top of the single crystal silicon membranes 904a-904d, resulting in a single crystal silicon structure. Other materials may also be used.

The additional layer 908 may have any suitable thickness to provide a desired total membrane thickness. For example, a given silicon membrane may have a first thickness, the additional layer 908 may have a second thickness, and thus a resulting third thickness (representing a sum of the first and second thicknesses) may be created. The first and second thicknesses may be equal to each other, or either may be larger than the other. The total thickness may be any suitable value, including any of those described herein for membrane thicknesses.

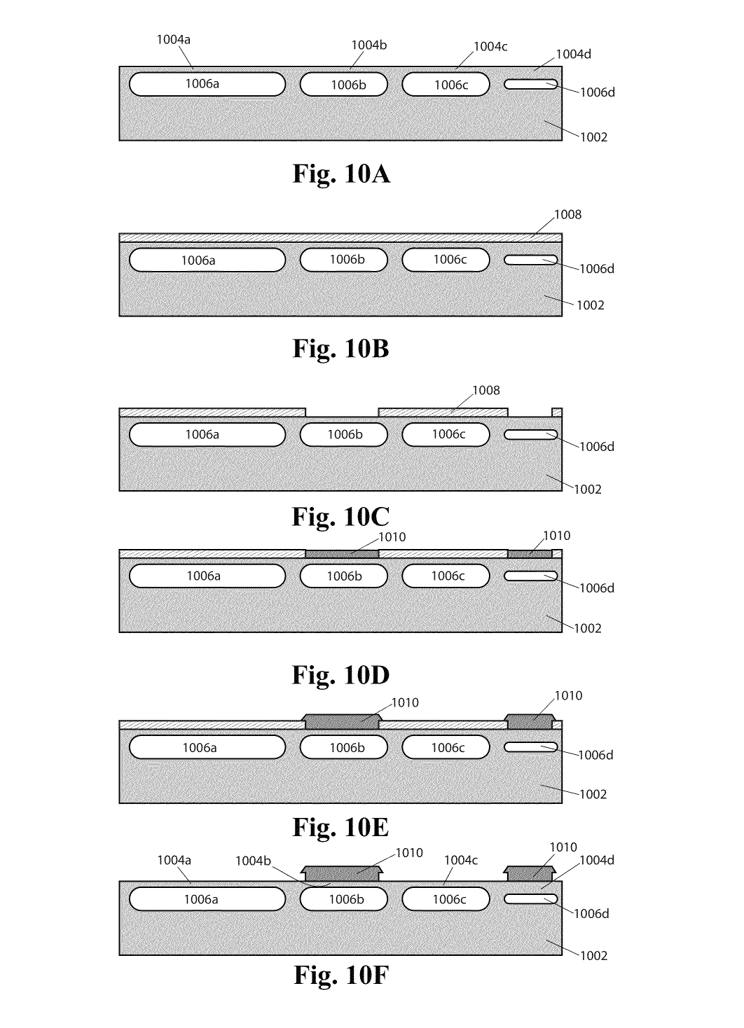

To achieve a wider range of membrane thicknesses than may be possible using the techniques described in connection with FIGS. 9A-9B, selective epitaxial growth (SEG) may be used, a non-limiting example of which is described in connection with FIGS. 10A-10F. Starting with a silicon wafer 1002 having membranes 1004a-1004d thinner than what is ultimately desired (see FIG. 10A), a thermal oxide 1008 is grown (see FIG. 10B), patterned, and etched (see FIG. 10C) as a mask. The membranes 1004a-1004d may be formed in any suitable manner and using any of the aspects described herein. The membranes may be formed above respective cavities 1006a-1006d. The illustrated patterning of the thermal oxide 1008 is non-limiting, as other patterns may be created.

Then, epitaxial silicon 1010 or some other epitaxial material is deposited in areas of exposed substrate silicon (see FIG. 10D) of the wafer 1002. Once the selectively grown film exceeds the thickness of the oxide mask (see, e.g., FIG. 10E), lateral epitaxial overgrowth (LEO) begins and the silicon 1010 begins to grow both vertically away from the substrate and laterally along the mask surface of thermal oxide 1008. Finally, once the thickness of interest of the silicon 1010 is reached, the thermal oxide 1008 is removed using standard liquid or vapor etch procedures or any other suitable removal techniques, as shown in FIG. 10F.

It should be appreciated that the reference to thermal oxide 1008 is a non-limiting example. Other mask materials may alternatively be used in the process flows illustrated in FIGS. 10A-10F. Also, the illustrated patterning and thickness are non-limiting, as alternatives may be used.

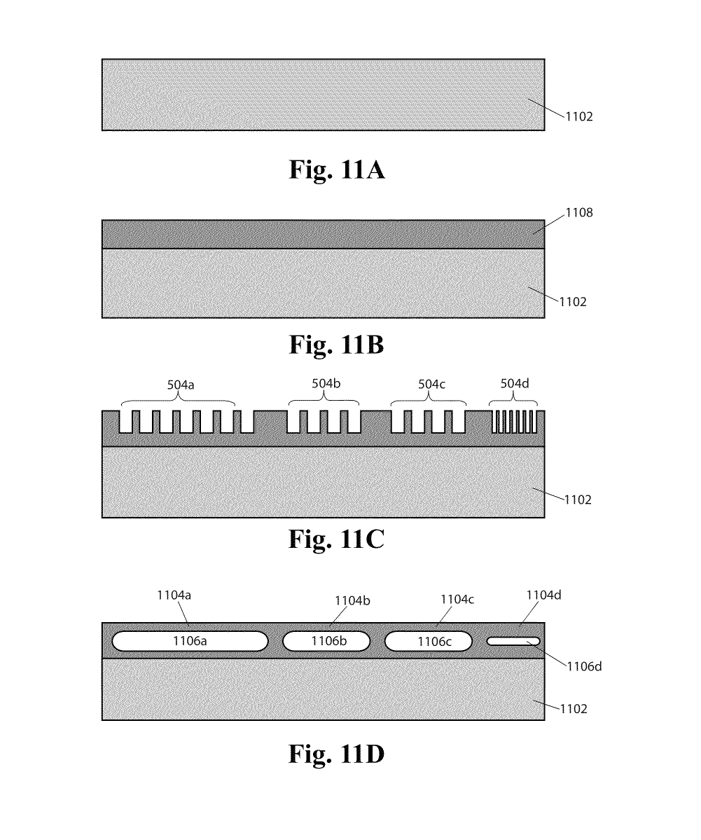

An alternate approach to expediting the membrane formation process is to change the composition of the wafer near the surface in such a way that the rate of trench reflow increases. An example of this approach is illustrated in FIGS. 11A-11D. A starting silicon wafer 1102 (FIG. 11A) is coated with a second material to form a layer 1108, as shown in FIG. 11B. The material of layer 1108 may include: doped Si, Ge, Si₁₋ₓGeₓ, Al, Cu, Ni, Au, W, Ag, Pt, any combination of such materials, or any other suitable material. At this step (the stage of FIG. 11B) the wafer may be annealed to achieve a thermodynamically stable alloy or compound near the surface.

The wafer is then patterned and etched as shown in FIG. 11C, for example to form trench patterns. In the non-limiting example of FIG. 11C, the trench patterns 504a-504d are formed, as previously described in connection with FIG. 5A. Other trench configurations may alternatively be formed. The patterning and etching illustrated in FIG. 11C may be performed using any suitable technology.

Trench reflow may then be performed as shown in FIG. 11D, in the manner described above with respect to the various aspects involving trench reflow to result in membranes 1104a-1104d above respective cavities 1106a-1106d. In the preferred embodiment, Si₁₋ₓGeₓ is used for layer 1108 as it is crystallographically similar to Si, but has a lower melting temperature and thus surface diffusion can proceed faster and/or at lower temperatures and/or at higher pressures. Compositionally graded Si₁₋ₓGeₓ, where the Ge atomic fraction x is varied as the film is deposited, may be used to accommodate stress due to the lattice mismatch between Si and Ge. The final membrane composition will be, in some embodiments, single crystal Si₁₋ₓGeₓ, which, in at least some instances, has superior acoustic properties to its polycrystalline form, and its defects and surface roughness can be managed by annealing and other techniques.

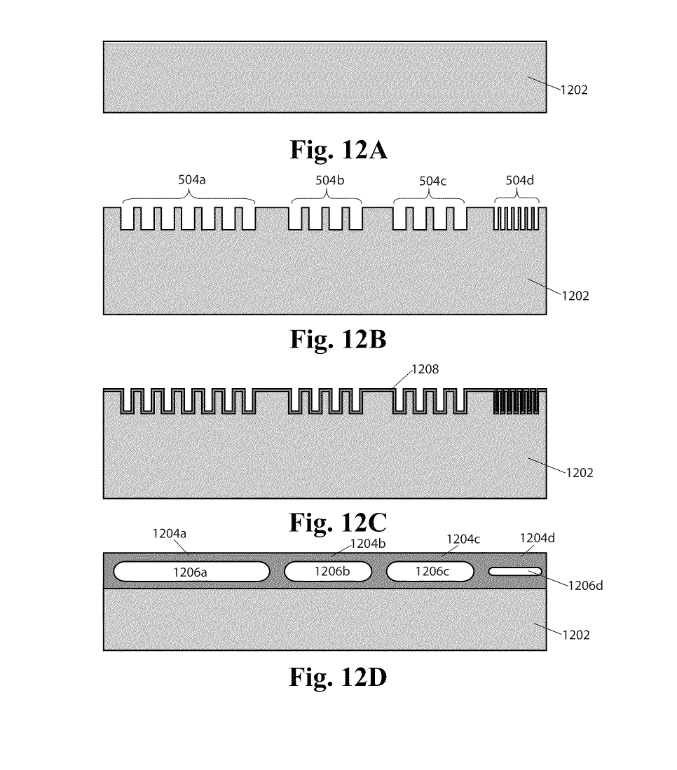

As an alternative to the process flow illustrated in FIGS. 11A-11D, deposition of a compositionally distinct layer from the silicon substrate may occur after the trenches have been etched in the substrate. A non-limiting example of such a process is illustrated in connection with FIGS. 12A-12D.

A silicon substrate 1202 may be provided, as shown in FIG. 12A. Then, as shown in FIG. 12B, trench patterns may be formed in the silicon substrate 1202. The trench patterns may be formed in any suitable manner, including any of those described herein. Non-limiting examples of resulting trench patterns include patterns 504a-504d, previously described. However, other trench patterns may be formed.

As shown in FIG. 12C, a layer 1208 of material compositionally different than the silicon substrate 1202 may be deposited to cover the trench patterns. The layer 1208 may be any of the materials previously described in connection with layer 1108, or any other suitable material.

Trench reflow may then be performed as shown in FIG. 12D, using any of the techniques described herein for trench reflow or any other suitable technique. Resulting membranes 1204a-1204d may be created above respective cavities 1206a-1206d.

The advantages of utilizing the implementation of FIGS. 12A-12D may include: 1) the surfaces of the trenches, where surface diffusion occurs, are the areas whose composition is changed, preserving most of the original silicon, 2) the aspect ratio of the trenches increases for a conformal deposition, and 3) the trench widths become narrower, potentially beyond the capabilities of the lithography. Again the non-limiting preferred embodiment is to use a Si substrate (e.g., as substrate 1202) and epitaxial Si₁₋ₓGeₓ film(s) (e.g., as layer 1208) to lower the melting point and accommodate the lattice mismatch stress.

As previously mentioned, use of the fabrication techniques described herein may offer benefits over SOI processing techniques, for example in the formation of stress free membranes with accurately controlled thicknesses (e.g., the thickness of the silicon layer may only be controlled to within approximately +/−0.5 microns using SOI techniques, compared to +/−0.02 microns using the techniques described herein). In addition, Applicants have appreciated that use of the techniques described herein may facilitate formation of through-silicon vias (TSVs), which may be more difficult to form if SOI techniques are used due to the insulating oxide layer associated with SOI wafers. For example, using the techniques described herein, the vias may be etched from the top-side of the substrate (e.g., from a top surface 116 of the substrate 110) and exposed by thinning the substrate from the backside after bonding to another wafer, also referred to as “blind vias.” Accordingly, in some embodiments, the TSVs may be smaller (e.g., only half the wafer thickness in some embodiments) than is attainable using SOI technology.

It should also be appreciated that the processing shown herein (e.g., the processing to form the apparatus described herein) may be performed on either the front side or back side of a substrate, or both. For example, it is possible to create cavities in the backside of the wafer at the same time as forming cavities in the front side of the wafer, and fabricate devices on the front and back. Alternatively, cavities (and corresponding membranes) may be formed only on a backside of a wafer and not on a front side. Also, it should be appreciated that the structures shown herein may be formed without the use of wafer bonding and without the use of SOI substrates, according to some embodiments.

The mechanical resonating structures described herein may be used as stand alone components, or may be incorporated into various types of larger devices. Thus, the various structures and methods described herein are not limited to being used in any particular environment or device. However, examples of devices which may incorporate one or more of the structures and/or methods described herein include, but are not limited to, tunable meters, mass sensors, gyroscopes, accelerometers, switches, filters, microphones, pressure sensors, magnetic field sensors and electromagnetic fuel sensors. According to some embodiments, the mechanical resonating structures described are integrated in a timing oscillator. Timing oscillators are used in devices including digital clocks, radios, computers, oscilloscopes, signal generators, and cell phones, for example to provide precise clock signals to facilitate synchronization of other processes, such as receiving, processing, and/or transmitting signals. In some embodiments, one or more of the devices described herein may form part or all of a MEMS.

Having thus described several aspects of at least one embodiment of the technology, it is to be appreciated that various alterations, modifications, and improvements will readily occur to those skilled in the art. Such alterations, modifications, and improvements are intended to be within the spirit and scope of the technology. Accordingly, the foregoing description and drawings provide non-limiting examples only.

In addition, while some references have been incorporated herein by reference, it should be appreciated that the present application controls to the extent the incorporated references are contrary to what is described herein.

What is claimed is:

1. A method, comprising:
forming a silicon membrane above a cavity in a silicon substrate, the silicon membrane having a first thickness; and
forming a layer of material having a second thickness on top of the silicon membrane to create a membrane having a third thickness, the third thickness representing a sum of the first and second thicknesses.

2. The method of claim 1, wherein the first and second thicknesses are equal.

3. The method of claim 1, wherein forming the silicon membrane above the cavity comprises forming a trench in the silicon substrate and annealing the silicon substrate.

4. The method of claim 1, wherein the layer of material is formed of silicon oxide.

5. The method of claim 1, wherein the layer of material is formed at least in part by selective epitaxial growth.

6. The method of claim 1, wherein forming the layer of material comprises depositing and patterning the layer of material.

7. A method, comprising:
forming a layer of material on a silicon substrate;
forming a plurality of trenches in the layer of material; and
annealing the substrate after forming the plurality of trenches in the layer of material on the silicon substrate.

8. The method of claim 7, wherein the layer of material comprises SiGe.

9. The method of claim 7, wherein the plurality of trenches forms a one-dimensional trench pattern arranged along one axis, wherein the trench pattern is characterized by:
a) differing trench widths among multiple trenches of the pattern; and/or
b) differing periods between multiple trenches of the pattern; and/or
c) at least one trench of the pattern having a width that varies along a length of the trench.

10. The method of claim 7, wherein annealing the substrate is performed for a sufficient duration to create a membrane above a cavity in the layer of material.

11. The method of claim 10, wherein the layer of material comprises SiGe.

12. A method, comprising:
forming a plurality of trenches in a silicon substrate;
depositing a conformal layer of material in the plurality of trenches; and
annealing the substrate after depositing the conformal layer of material in the plurality of trenches.

13. The method of claim 12, wherein the layer of material comprises SiGe.

14. The method of claim 12, wherein the plurality of trenches forms a one-dimensional trench pattern arranged along one axis, wherein the trench pattern is characterized by:
a) differing trench widths among multiple trenches of the pattern; and/or
b) differing periods between multiple trenches of the pattern; and/or
c) at least one trench of the pattern having a width that varies along a length of the trench.

15. The method of claim 12, wherein annealing the substrate is performed for a sufficient duration to create a membrane above a cavity.
